(19) United States
(12) Patent Application Publication
(10) Pub. No.: US 2004/0221209 A1
(43) Pub. Date: Nov. 4, 2004

(54) Method for overriding interference in digital audio signal transmission

(76) Inventors: Claus Kupferschmidt, Wedemark (DE); Gerd Penshorn, Edemissen (DE); Arnd Wendland, Nordstemmen (DE)

Correspondence Address: Richard L Mayer, Kenyon & Kenyon, One Broadway, New York, NY, 10004, US

(21) Appl. No.: 10/481,776

(22) PCT Filed: Apr. 12, 2002
(86) PCT No.: PCT/DE02/01368

(30) Foreign Application Priority Data
Jun. 22, 2001 (DE) 101 30 233.9

(51) Int. Cl. G01R 31/28

(52) U.S. Cl. 714/713

(57) ABSTRACT

A method for overriding interference in a reproduced audio signal which is derived from a digital signal, the reproduced audio signal being attenuated as a function of data error statistics of the digital signal, which is distinguished by the fact that a substitute signal is superimposed on the attenuated audio signal as a function of the data error statistics of the digital signal. The method advantageously ensures that, even in the case of very noisy digital input signals, a signal is acoustically reproduced at any time, so that the volume set on an appropriately equipped radio receiver is able to be anticipated realistically for the user at any time. This avoids deceiving the user about the volume of the reproduction that is actually set, which in the case of a very noisy received signal, as a result of the interruption of an audio reproduction, is no longer determinable according to the related art.

### FIELD OF THE INVENTION

The present invention relates to a method for overriding interference in a reproduced audio signal derived from a digital signal.

### BACKGROUND INFORMATION

In systems of digital transmission technology in mobile communications, as a result of non-ideal transmission channels, particularly because of multipath reception, reflection, shading and attenuation, interference occurs in the digital transmission signal which results in bit errors. To a certain extent, these may be corrected, at the transmitting end, by suitable channel coding or, at the receiving end, by suitable decoding. However, if the data error rate in the digital transmission signal rises above a predefined value, correcting the bit errors is no longer possible, so that they have an effect in the form of clearly perceptible interference in the data content transmitted by the digital transmission signal, as would take place, for example, in the case of a digitally transmitted audio broadcast signal on an audio signal to be reproduced.

In the case of analog systems, at diminishing reception quality, there is a gradual degradation in the quality of the audio signal contained in the broadcast signal, which is countered, for example, by analog FM broadcast receivers having a stereo/mono switchover and muting of the audio signal to be reproduced.

In digital systems there is no such gradual or creeping degradation of the signal as a function of interference in the transmission signal. The quality of digitally transmitted audio signals rather moves in a range of either very good quality or very bad quality. In order to implement a sliding transition from good to bad quality, in the case of digital systems, one makes use, for these, of an imitation of this method (graceful degradation). The methods used there for masking errors, on the other hand, in the case of a high data error rate, tend to set the signal lower or completely silent. In the case of long-lasting muting, as a result of enduringly high data error rate of the transmission signal, this can lead to confusion of the user, to whom it is suggested that the radio receiver reproduces only a very soft audio signal or none at all. This may prompt the user to increase the level of loudness for the reproduction of the audio signal via the sound volume control. Moreover, the so-called gurgling within the reproduced audio signal, that is caused by bit errors, is perceived, as a rule, as being very unpleasant. If now the digital radio signal, after a user-initiated volume increase, is received again at a sufficient quality, that is, having a data error rate which makes possible the correction of the data errors, the audio reproduction which, as a result of reception deterioration, was toned down before or muted, is suddenly taken up again, which, after the raising of the reproduction volume may lead to damage of the connected loudspeakers and possibly also of the hearing of the user.

Patent Abstracts of Japan at JP-A-10-308708 describes a system for receiving and reproducing digitally transmitted audio data, which has an error detection and an error correction, in the case of a non-noisy or noisy, but correctible received signal the audio signals contained therein being reproduced, whereas in the case of a considerably noisy reception signal section, a noise signal is generated using a noise signal generator while using a received signal, and it is additively superimposed on the audio data to be reproduced.

### SUMMARY OF THE INVENTION

The method according to the present invention has the advantage that a reliable basis for judgment is conveyed to the listener for the instantaneously pre-selected reproduction volume for an audio signal transmitted by a digital radio signal. This avoids the danger that the user disadvantageously increases the volume during an attenuation or muting of the audio reproduction, as a result of a high data error rate of the received digital radio signal. In addition, the effect of the bit errors within the digital radio signal, perceived as unpleasant in the form of gurgling within the reproduced audio signal, is reduced.

For this it is provided, according to the present invention, that in a method for overriding interference in a reproduced audio signal that is derived from a digital signal, the reproduced audio signal being attenuated as a function of data error statistics of the digital signal, a substitute signal be superimposed on the attenuated audio signal as a function of the data error statistics of the digital signal.

It is of particular advantage that the reproduced audio signal is attenuated in a frequency-selective manner as a function of the data error statistics of the digital signal, and that the substitute signal is superimposed in a frequency-selective manner. In this fashion, a further approach of the behavior of a digital radio receiver to that of an analog, particularly an FM, radio receiver makes the two more alike. Thus, analog FM radio receivers, as a result of a deterioration in reception quality of a received analog radio signal, as a rule carry out a so-called high cut, i.e. a lowering of high-frequency components of the audio signal to be reproduced.

On account of the fact that audio signals in the range of low frequencies are characterized more by tonal components, and higher frequency ranges are distinguished more by noisy signal components, the substitution of higher frequency ranges by substitute noise leads to a better signal quality, and thus to better auditory perception after the error concealment.

Also, because of frequency-selective signal attenuation and signal substitution, twittering interference in the audio signal caused by bit errors, so-called birdies, are reduced, so that the subjective perception of the audio signal is improved.

An especially good estimating basis for the actually set volume of the digital radio receiver is afforded by the superimposition of the substitute signal's fully compensating for the attenuation of the audio signal as a result of a high data error rate, so that the volume of the overall audio signal formed from the superimposition of the attenuated audio signal and the substitute signal corresponds to that of an audio signal that is received and reproduced without interference.

The substitute signal may advantageously be formed as a noise signal, a sinusoidal tone or an identifying tone or as a stored or synthesized voice signal. Especially in the case of a noise signal as the substitute signal, this may also advantageously be adapted with respect to its frequency response characteristic to the psychoacoustical properties of human hearing.

Furthermore, the substitute signal may be additively superimposed on the attenuated audio signal, either in the time domain or in the frequency domain.

The method according to the present invention advantageously stands out in that it may basically be applied equally to all audio formats and all audio signals transmitted in digital form, particularly digital radio signals of various standards, such as DAB, DSR or the like.

Moreover, the method is implemented especially simply, since the control both of the degree of attenuation of the reproduced audio signal and the degree of superimposition of the substitute signal is controllable as a direct function of a data error rate of the received digital radio signal recorded with the aid of data error statistics.

Moreover, it is of particular advantage that the method according to the present invention does not in any way affect the source decoding of the audio data from the received digital radio signals, so that the method is also disconnectable without influencing the decoded audio signals.

### BRIEF DESCRIPTION OF THE DRAWINGS

FIG. 1 shows a block diagram of a system for carrying out the method according to the present invention with respect to the example of an MPEG audio coder having integrated, so-called error concealment, in which a substitute signal is superimposed in the frequency on the audio signal that is attenuated as needed.

FIG. 2 shows the superimposition of audio signal and substitute signal in the frequency domain.

### DETAILED DESCRIPTION

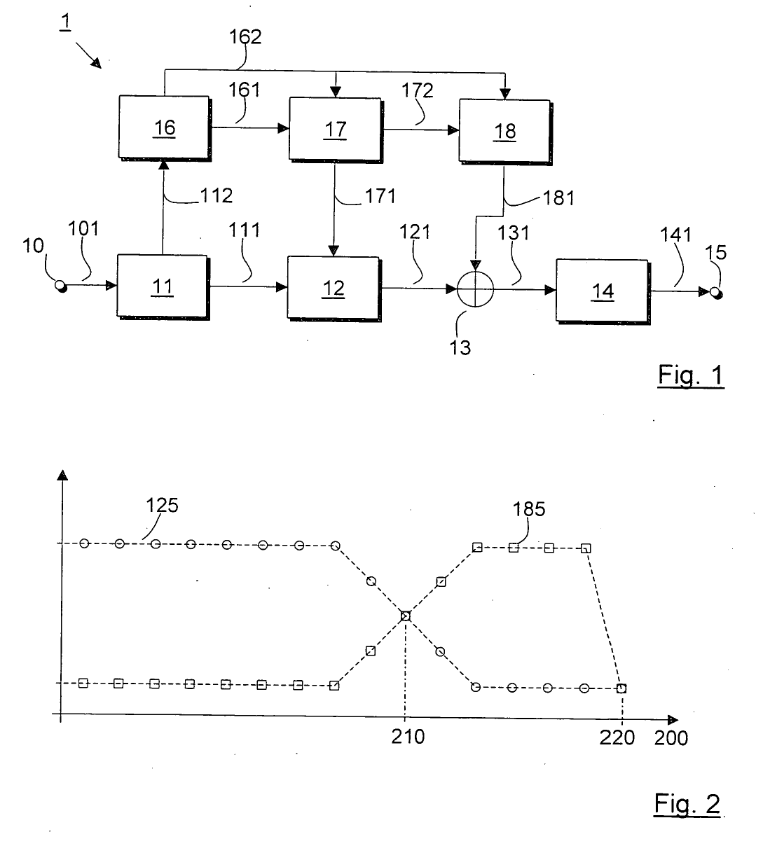

FIG. 1 shows an audio decoder MPEG 1, 2 layer 2 having integrated bit veiling and data error veiling. In this context, MPEG denotes a method developed by Fraunhofer Company for coding or compressing digital audio data. The audio coder mentioned is thus used for decoding the digital audio data present in MPEG format.

MPEG-coded digital audio signal 101, which is applied at a data input 10 of the system, is supplied to a decoder 11. The decoding of the coded digital audio system takes place in decoder 11, as well as an error detection and possibly an error correction of the received data signal. Audio signal 111 applied at a first output of decoder 11 is supplied to a filtering circuit 12, which may be designed, for example, in the form of an equalizer, but optionally also as in the form of a bandpass filter having an adjustable frequency limit, steepness of curve and overall amplification factor. Audio signal 121 which has been evaluated by filter 12 is supplied to a superimposed connection 13, in the present case in the form of an adder 13. Total audio signal 131 which can be tapped off from the output of adder 13 is transformed inversely in an inverse filter 14 from the frequency domain into the time domain, so that at output 15 of circuit configuration 1 there is applied overall audio signal 141 which is reproducible via the loudspeakers of an audio system that includes circuit configuration 1.

The necessity of an inverse transformation 14 comes about due to the fact that MPEG-coded signals are present in the frequency domain, and thus each sampling value of the audio signal is present in the form of its spectral distribution.

At a second output of decoder 11, an error signal 112, representing the data error rate of the received digital signal, may be tapped, which is supplied to a circuit configuration 16 for the purpose of generating error statistics. At a first output of error statistics generation 16, an error statistics signal 161 may be tapped, which indicates the data error rate of the digital signals applied at input 10 of circuit configuration 1. This is supplied to an assignment circuit 17, in which, as a function of error statistics signal 161, parameters are selected for controlling equalizer 12 or rather filter 12. As an example, in the case of a signal that has almost not been interfered with, at data input 10, equalizer 12 or rather filter 12 is controlled via a filter control signal 171 in such a way that decoded audio signal 111 supplied to it may essentially be tapped unchanged at the output of the equalizer 12 or rather filter 12. As opposed to this, when there is an increasing data error rate, in assignment circuit 17, a set of parameters for controlling equalizer 12 or rather filter 12 is selected in such a way that, at first, higher frequency proportions of audio signal 111 are attenuated, but, with further increasing data error rate, increasingly also lower frequency proportions of audio signal 111, and finally the entire audio signal are attenuated.

According to one preferred specific embodiment of the present invention, assignment circuit 17 also has a bit error signal 162 supplied to it which is also generated by error statistics generator 16, and which represents the bit errors of the digital input signal. Bit error signal 162 is derived from the internal tests for frame headers or from data errors themselves, and is a direct measure of the instantaneous error rate. Compared to that, error statistics signal 161, based on low-pass filter characteristics, is a comparatively slowly reacting signal to errors in the digital signal.

A data set 171, selected as a function of the data error rate or error statistics signal 161 representing the data error rate, according to a preferred specific embodiment, in addition to bit error signal 162, for controlling equalizer 12 or rather filter 12, is supplied to the latter by assignment circuit 17. Furthermore, a data set 172 of filter parameters inverted to selected data set 171 is supplied to a substitute signal generator 18, to which, in addition, according to the aforesaid preferred specific embodiment of the present invention, bit error signal 162 is supplied by error statistics generator 16.

According to the preferred specific embodiment of the present invention, substitute signal generator 18, as a function of second equalizer parameter or filter parameter 172 supplied to it, and as an additional function of bit error signal 162, generates a substitute signal formed corresponding to these parameters, which is supplied to a second input of superimposition circuit 13. Consequently, at the output of superimposition circuit 13, an overall audio signal 131 may be tapped, which is made up of a superimposition, in the present case an addition, of the audio signal attenuated according to first equalizer parameters or filter parameters 171 using equalizer or filter 12 and substitute signal 181 formed according to second equalizer parameters or filter parameters 172.

According to one preferred specific embodiment of the present invention, filter parameter set 172 supplied to substitute signal generator 18 is designed in such a way that the filter curves of filter 12 and those of the second filter for the evaluation of the substitute signal provided in substitute signal generator 18 are mutually compensating, so that, in sum, a linear frequency response characteristic is brought about. This pattern of the filter curves may also be seen, for example, in FIG. 2, where amplitude-frequency characteristic 125 of filter 12 and additional amplitude-frequency characteristic 185 of the second filter provided in substitute signal generator 18 for evaluating the substitute signal are plotted against frequency 200. As may be seen from the figure, amplitude-frequency characteristic 125 of filter or equalizer 12, which is assigned to a certain degree of error or a certain data error rate of the input signal, is reduced from a maximum value having a 3 dB frequency limit 210 and closes at the value 0. By contrast, additional frequency response characteristic 185, which is assigned to the same data error rate or data error statistics, increases from a value of 0 via 3 dB frequency limit 210 to a value which corresponds to the maximum amplitude of amplitude-frequency characteristic 125. Since above a maximum frequency 220 an audio signal reproduction is in any case not perceptible by the human ear, additional amplitude-frequency characteristic 185 drops off to the value 0 on its way to this maximum frequency 220.

As may be seen in FIG. 2, the two frequency response characteristics 125 and 185 of filter 12 and substitute signal generator 18 superimpose to an overall linear and constant frequency response characteristic.

According to one preferred specific embodiment of the present invention, substitute signal generator 18 is designed in such a way that a neutral noise signal is generated in it as substitute signal. Consequently, at output 15 of circuit 1 of FIG. 1, an overall audio signal 141 comes about which is composed of a superimposition of an audio signal attenuated according to the measured data error rate and of a noise signal that is also generated according to the data error rate. When heading towards lower data error rates, the proportion of audio signal 121 will increase at the expense of noise signal 181, and by contrast, in the case of increasing data error rate, audio signal 121 is replaced increasingly by noise signal 181.

According to one advantageous refinement of the present invention, it may, on the other hand, be provided that the substitute signal is designed in the form of a sinusoidal tone or identifying tone, or of a superimposition of several sinusoidal or identifying tones. In addition, it may be provided that the substitute signal is a stored or a synthesized voice signal. Substitute signal 181 may also be designed in the form of a noise that is adapted to the physiology of the human ear and is appropriately filtered.

As was mentioned at the beginning, the present method is basically applicable to every single kind of digitally coded audio signals. Therefore it is within the scope of the present invention that any digital coded audio signal 101 is able to be supplied to data input 10. The decoder is then adapted, or is to be adapted to the respective SUBSTITUTE SPECIFICATION kind of digitally coded audio signal 101, so that, at its output, a correctly decoded audio signal 111 may be tapped off.

The present invention is also fundamentally applicable to audio signals present in the time domain, and for this case, inverse transformation 14 may be omitted, and then, additionally, filter 12, decoder 16, assigning circuit 17 and substitute signal generator 18 are appropriately adjusted.

1-3. (Canceled).

4. A method for overriding interference in a reproduced audio signal which is derived from a digital signal, the method comprising:
attenuating the reproduced audio signal in a frequency-selective manner as a function of data error statistics of the digital signal; and
superimposing a substitute signal on the audio signal in a frequency-selective manner as a function of the data error statistics of the digital signal.

5. The method according to claim 4, wherein the superimposing of the substitute signal compensates for the attenuation of the audio signal.

6. The method according to claim 4, wherein the substitute signal is formed by at least one of a noise signal, a sinusoidal tone, an identifying tone, and a voice signal.
